(19) United States
(12) Patent Application Publication
(10) Pub. No.: US 2012/0014538 A1
(43) Pub. Date: Jan. 19, 2012

(54) AUDIO EQUIPMENT AND A CONTROL METHOD THEREOF

(76) Inventors: Serkan Bozkurt, Istanbul (TR); Haluk Sahin, Istanbul (TR); Hasan Samet Yaslan, Istanbul (TR)

(21) Appl. No.: 13/142,798

(22) PCT Filed: Dec. 16, 2009
(86) PCT No.: PCT/EP2009/067274

§ 371 Date: Oct. 3, 2011

(30) Foreign Application Priority Data
Dec. 29, 2008 (TR) A 2008/09944

(51) Int. Cl. H03G 3/00

(52) U.S. Cl. 381/107

(57) ABSTRACT

Method of controlling the volume level of a system that consisting of an audio equipment (1) comprising a micro-processor (2) and a loudspeaker (4), and of an external device (H) connected to the audio equipment (1). The external device (H) applies a first gain (G2) to an audio signal (S) before providing a first amplified audio signal (O2) to the audio equipment (1). The audio equipment (1) applies a second gain (G1) before transmitting a second amplified audio signal (O1) to the loudspeaker (4). A user of the system sets a minimum audible sound level and a maximum sound level. The microprocessor (2) calculates the second gain (G1) as a function of the first gain (G2), such that the sound level is within the limits set by the user. Thus, the user sets the volume level of the system by just setting the first gain (G2) of the external device (H).

### TECHNICAL FIELD

The present invention relates to an audio equipment, which automatically adjusts its own volume level according to the volume level of the external device connected thereto, and relates to a control method thereof.

### THE PREVIOUS TECHNIQUE

In devices such as DVD player, satellite receiver and set top box, the audio signal is electrically generated but not converted into audible sound. The devices, which electrically generate the audio signal but do not convert it into audible sound, will be hereinafter called the “external device”.

Users listen to the sound from another electronic device such as television or home theater system, to which the external devices are connected and which can generate an audible sound. The electronic devices, which can generate an audible sound from the audio signal, will be hereinafter called the “audio equipment”.

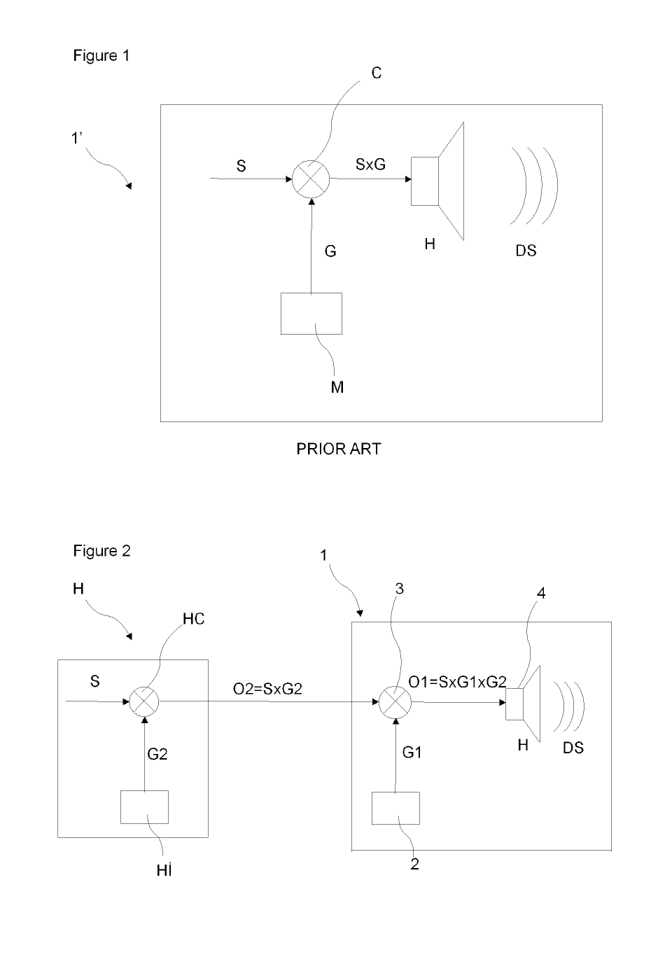

In the state of the art audio equipment (1′), the heard sound (DS) is most essentially the sum of the loudspeaker's effect (LE) with the product of the audio signal (S) and the applied gain (G) (FIG. 1). In this situation, the heard sound (DS) can be expressed by the formula number (1).

DS=(S×G)+LE (1)

The audio signal (S) is amplified before being applied to the loudspeaker

(H) of the audio equipment (1′). In the amplification process, the audio signal (S) is multiplied by a gain coefficient (G) by means of a multiplier (C). When the amplified audio signal (S×G) is applied to the loudspeaker (H), an additive effect (LE) of the loudspeaker occurs to this signal, also, and the amplified audio signal (S×G) is converted into audible sound (DS).

The gain (G) that will be applied to the audio signal (S) is generally controlled by a microprocessor (M). The gain (G) that is controlled by the microprocessor (M) is generally adjusted by the user. The user performs the gain adjustment process by using the tools provided for volume level adjustment by the audio equipment (1′). These tools can be the remote control, the volume level indicator on the menu, the control buttons on the equipment or the combinations thereof. The volume level indicator visualizes the gain coefficient (G) to the user. While the user performs volume level adjustment, the user controls the volume level indicator that is in fact, the gain (G) applied to the audio signal (S) (FIG. 1). The user generally utilizes the control buttons on the equipment or the remote control for this process.

Both external devices and audio equipments provide their users the opportunity of adjusting the volume level. This situation causes problems about the volume level in the embodiments wherein the external devices and the audio equipments are connected to each other.

In the state of the art, when the audio equipment and the external device

(H) are connected to each other, the external device (H) applies a gain (G2) to the generated audio signal (S). Because, the external device (H) provides the user the opportunity of controlling the volume level. Afterwards, the audio equipment, also, applies a gain (G1) to the signal at the output of the external device (H) (O2=S×G2). Because, the audio equipment provides the user the opportunity of controlling the volume level also. Therefore, the heard sound (DS) is provided by the formula number (2) (FIG. 2).

DS=(S×G1G2)+LE (2)

In systems wherein the audio equipment and the external device (H) are connected to each other, the volume level can be separately controlled by the gains G1 and G2. In some cases, the user performing volume level adjustment in order to bring the heard sound (DS) to the desired level is obliged to perform volume level adjustment at both devices. This means that in systems wherein the volume level adjustment is performed by remote control, the user uses the remote control of both the audio equipment and the external device (H). Using two remote controls for volume level adjustment is an uncomfortable situation for the user.

In a model system, it is assumed that the external device (H) is a satellite receiver and the gain coefficient G2 varies between 0 and 15. In this model system, it is assumed that the audio equipment generating audible sound is a television and the gain coefficient G1 also varies between 0 and 15. In this situation, in the model system wherein the satellite receiver and the television are connected to each other, the total gain (GT) that can be applied to the audio signal will vary between 0 and 225.

Since the user does not want to use two remote controls, the user adjusts the volume of the satellite receiver or television to a certain level and then controls the volume level of the system by the remote control of the other device. In the model system formed by the satellite receiver and the television, since the television is used as the display unit and the sound generating unit, the remote control of the television is used only for volume level adjustment and turning on/off the television. Therefore, in order to be able to control the system by a single remote control, the user generally fixes the volume level of the television to a certain value and controls the whole system by the remote control of the satellite receiver.

In a model scenario, it is assumed that the user fixes the volume of the television to a level corresponding to a gain value (G1) of 5 by means of the remote control and the volume level indicator visible on the screen. Since the gain (G2) of the satellite receiver can vary between 0 and 15, the total gain (GT) that can be applied to the audio signal by the system varies between 0 and 75.

In this scenario, the system cannot generate some of the sound that can be potentially generated. Because, the maximum total gain (GT) that can be applied to the audio signal by the system is limited to 75 and the gain values remaining between 75 and 225 cannot be applied to the audio signal. When the upper limit GT=75 remains insufficient or the noise increases in the environment the user performs watching and/or listening, the user is obliged to increase the gain value G1, that is, the volume level of the television by using the remote control of the television. As a result, the user either cannot use all of the sound that can be generated by the system or is obliged to use the remote control of the television together with the remote control of the satellite receiver.

In a second scenario, it is assumed that the user fixes the volume of the television to a level corresponding to a gain value (G1) of 15 by means of the remote control and the volume level indicator. Since the gain (G1) of the satellite receiver can be changed between 0 and 15, the total gain (GT) that can be applied to the audio signal by the system varies between 0 and 225. However, the first volume level the user can hear from the system after the volume level of 0 coincides with the gain value GT=15. Because, when the volume of the satellite receiver is brought to the level corresponding to the gain value (G2) of 1, the gain that will be multiplicatively processed to the audio signal in the system is 15 since the gain value (G1) of the television is fixed to 15. In this situation, the system cannot apply the total gain values between 0 and 14 to the audio signal.

As a result of this, the chance of performing fine adjustment by the user who performs listening in a noiseless environment expires. In this embodiment, the user cannot use the lower level of the audio band of the system and is obliged to use the remote control of the television for fine adjustment again.

As a result, in systems wherein the audio equipment and external devices (H) are connected to each other, users are obliged either to actively use the remote controls of both devices or to accept not using some of the sound that can be generated in the system.

In the state of the art U.S. Pat. No. 5,130,665, the user determines the minimum volume level and the maximum volume level desired to be heard from the said system. Then, the system brings the low level sounds to the minimum volume level desired to be heard, and lowers the sounds, which are above the maximum volume level desired to be heard, below the maximum volume level desired to be heard. The said system compares the audio signals in order to be able to bring them to the desired maximum and minimum volume levels.

In the U.S. of America Document No US2005232444, another state of the art embodiment, the user determines a sound level value for each external appliance connected to the main appliance, and the determined sound level values are added to the sound level, which will be heard from the system, according to the type of the external appliance connected to the main appliance.

Another embodiment wherein the sound level can be automatically adjusted is described in the Korean Patent Document No KR20020053219.

### BRIEF DESCRIPTION OF THE PRESENT INVENTION

The aim of the present invention is the realization of an audio equipment that automatically determines the gain, which will be applied to the audio signal, according to the volume level of the external device, and of a control method thereof.

Another aim of the present invention is to provide the user to perform listening from the system wherein the external device and the audio equipment are connected to each other, in the volume level interval the user determines, by using only the remote control of the external device.

The audio equipment realized in order to attain the aim of the present invention, explicated in the first claim and the respective claims thereof, comprises at least one microprocessor, at least one multiplier and at least one loudspeaker. At least one external device, which electrically generates the sound, is connected to the audio equipment. In the system, the sound is converted into audible sound by means of the loudspeaker the audio equipment comprises. The gain factor of both the audio equipment and the external device is applied to the sound heard from the loudspeaker.

While generating the sound, the external device applies a gain factor to the audio signal according to the volume level the user has determined by the remote control. Afterwards, the audio signal that is amplified according to this gain factor is transmitted to the audio equipment.

In correspondence to the external device minimum gain value that generates the audible sound, the user only once determines the minimum volume level on the audio equipment that is desired to be heard from the loudspeaker of the audio equipment. Again in correspondence to the external device maximum gain value, the user only once determines the maximum volume level on the audio equipment that is desired to be heard from the loudspeaker of the audio equipment. Afterwards, the external device gain value that generates the minimum audible sound and the maximum gain value of the external device, and the gain values that correspond to the volume levels determined by the user for these predetermined gain values are saved in the audio equipment. The product of the audio equipment gain value that is determined in the audio equipment and that corresponds to the minimum volume level the user desires to hear, and the external device gain value that generates the minimum audible sound determines the minimum total gain that can be applied to the audio signal. This forms the minimum sound that can be heard from the loudspeaker, that is, from the system. The product of the audio equipment gain value that is determined in the audio equipment and that corresponds to the maximum volume level the user desires to hear, and the maximum gain value of the external device determines the maximum total gain that can be applied to the audio signal. This forms the maximum sound that can be heard from the loudspeaker, that is, from the system.

When the user changes the volume level of the external device, the gain value corresponding to the new volume level is transmitted to the audio equipment. The audio equipment calculates the fraction of the gain value transmitted by the external device in the gain value interval of the external device. The audio equipment then determines the gain, which will be applied to the audio signal by the audio equipment, such that it will correspond to the same fractional value in its own gain value interval determined by the user, and applies it to the audio signal. Thus, by using only the remote control of the external device, the user can perform listening in the volume level interval the user desires to hear.

### DETAILED DESCRIPTION OF THE PRESENT INVENTION

The audio equipment and the control method thereof, realized in order to attain the aim of the present invention, is illustrated in the attached figures, where:

FIG. 1—is the schematic view of an audio equipment in the state of the art.

FIG. 2—is the schematic view of the audio equipment of the present invention as connected with the external device.

The elements illustrated in the figures are numbered as follows:

1. Audio equipment

2. Microprocessor

3. Multiplier

4. Loudspeaker

The audio equipment (1) comprises at least one microprocessor (2), at least one multiplier (3) and at least one loudspeaker (4).

In the audio equipment (1) control method of the present invention, an external device (H) is connected to the audio equipment (1).

The external device (H) comprises at least one microprocessor (HI) and at least one multiplier (HC).

The following symbols are used for explicating the audio equipment (1) of the present invention and the control method thereof:

S: Audio signal generated in the external device (H)

G1: Gain applied to the audio signal (O2) at the external device (H) output in the audio equipment (1)

G1_{kullanici}_{_{—}}ₘᵢₙ: which is applied to the audio signal (O2) at the external device (H) output in the audio equipment (1) and which corresponds to the minimum volume level the user desires to hear

G1_{kullanici}_{_{—}}ₘₐₓ: which is applied to the audio signal (O2) at the external device (H) output in the audio equipment (1) and which corresponds to the maximum volume level the user desires to hear

G2: Gain applied to the audio signal (S) in the external device (H)

G2ₘᵢₙ: Gain value which is applied to the audio signal (S) in the external device (H) and which forms the minimum audible sound

G2ₘₐₓ: Maximum gain value applied to the audio signal (S) in the external device (H)

DS: Sound the user hears from the loudspeaker (4)

GT: Total gain applied to the audio signal by the audio equipment (1) and the external device (H)

O1: Audio signal applied to the loudspeaker (4)

O2: Audio signal at the external device (H) output

In the control method of the present invention, the user determines the minimum audible volume level of the external device (H), and the gain value (G2ₘᵢₙ) corresponding to this volume level is saved in the audio equipment (1). Then, in correspondence to the minimum audible volume level of the external device (H), the user determines the minimum volume level desired to be heard from the audio equipment (1), and the gain value (G1_{kullanici}_{_{—}}ₘᵢₙ) corresponding to this level is saved in the audio equipment (1). Thus, the minimum sound the user will hear from the loudspeaker (4) is determined by the product of the gains G2ₘᵢₙ and G1_{kullanici}_{_{—}}ₘᵢₙ.

Afterwards, the user determines the maximum volume level of the external device (H), and the gain value (G2ₘₐₓ) corresponding to this level is saved in the audio equipment (1). In the next step, in correspondence to the maximum volume level of the external device (H), the user determines the maximum volume level desired to be heard from the audio equipment (1), and the gain value (G1_{kullanici}_{_{—}}ₘₐₓ) corresponding to this level is saved in the audio equipment (1). Thus, the maximum sound the user will hear from the loudspeaker (4) is determined by the product of the gains G2ₘₐₓ and G1_{kullanici}_{_{—}}ₘₐₓ.

When these four values are saved in the memory, the volume level interval that will be formed by the audio equipment (1), hence by the system, is determined. The total gain (GT) that will be applied for forming this volume level interval varies between G2ₘᵢₙ×G1_{kullanici}_{_{—}}ₘᵢₙ and G2ₘₐₓ×G1_{kullanici}_{_{—}}ₘₐₓ.

In the control method of the present invention, as the user changes the volume level of the external device (H), the gain value (G2) corresponding to the new volume level is transmitted to the audio equipment (1). A wired communication channel such as CEO or SCART, or a wireless communication channel such as Bluetooth can be used for this process.

After the audio equipment (1) microprocessor (2) receives the data of new gain value (G2) of the external device (H), it calculates the fraction of the external device gain value (G2) between the external device (H) gain values G2ₘᵢₙ and G2ₘₐₓ. Then, the microprocessor (2) determines the gain value (G1), which will be applied to the audio signal (O2) by the microprocessor (2), such that it will correspond to the same fractional value between G1_{kullanici}_{_{—}}ₘᵢₙ and G1_{kullanici}_{_{—}}ₘₐₓ, and applies it to the audio signal (O2).

For example, the external device (H) gain value which forms the minimum audible sound is 1 (G2ₘᵢₙ=1), and the maximum gain value of the external device (H) is 15 (G2ₘₐₓ=15). These values are saved in the memory of the audio equipment (1). First, the user adjusts the volume level of the audio equipment (1) in order to determine the minimum sound desired to be heard from the system for the volume level corresponding to the value G2ₘᵢₙ=1. The value G1_{kullanici}_{_{—}}ₘᵢₙ corresponding to this level is saved in the memory of the audio equipment (1). Then, the user adjusts the volume level of the audio equipment (1) in order to determine the maximum sound desired to be heard from the system for the volume level corresponding to the value G2ₘₐₓ=15. The value G1_{kullanici}_{_{—}}ₘₐₓ corresponding to this level is saved in the memory of the audio equipment (1). For example, when the user performs volume level selections and selects the values G1_{kullanici}_{_{—}}ₘᵢₙ=5 and G1_{kullanici}_{_{—}}ₘᵢₙ=10, the total gain (GT) that can be applied to the audio signal varies between 5 and 150. In this example, when the user brings the volume of the external device (H) to the level that corresponds to the gain value G2=3, the value G2=3 is transmitted to the audio equipment (1) by means of the external device (H). The audio equipment (1) that takes on the value G2=3 calculates its fractional value between G2ₘᵢₙ and G2ₘₐₓ as 0.2 or 20%. Then, the audio equipment (1) determines the gain value (G1), which will be applied to the audio signal (O2) by the audio equipment (1), such that it will correspond to 20% of the interval G1_{kullanici}_{_{—}}ₘᵢₙ and G1_{kullanici}_{_{—}}ₘₐₓ, that is, G1=6, and applies it to the audio signal (O2). In this example, GT=18.

In the audio equipment (1) control method of the present invention, when the user performs selections regarding volume levels, the operation interval of the total gain (GT) that will be applied to the audio signal is determined. Therefore, the user determines the volume level interval, which will be formed by the system comprising the external device (H) and the audio equipment (1), according to the desire of the user. By the transmission of the external device (H) gain value (G2) to the audio equipment (1) and by the audio equipment (1) determining the gain (G1), which will be applied to the audio signal (O2) by the audio equipment (1), by considering the limits determined by the user, the user is not required to use the remote control of the audio equipment (1).

1. An audio equipment (1) comprising at least one microprocessor (2), at least one multiplier (3) and at least one loudspeaker (4), characterized by a microprocessor (2)
which saves the external device (H) gain value (G2ₘᵢₙ) that forms the minimum audible sound, and in correspondence to this value, the minimum volume level gain value (G1_{kullanici}_{_{—}}ₘᵢₙ) of the audio equipment (1) determined by the user,
which, furthermore, saves the maximum gain value (G2ₘₐₓ) of the external device (H), and in correspondence to this value, the maximum volume level gain value (G1_{kullanici}_{_{—}}ₘₐₓ) of the audio equipment (1) determined by the user, and
which calculates the fraction of the external device (H) gain value (G2), corresponding to the new volume level, between the external device (H) gain values G2ₘᵢₙ and G2ₘₐₓ, and which determines the gain (G1) that will be applied to the audio signal (O2) by the microprocessor (2), such that it will correspond to the same fractional value between the gain values G1_{kullanici}_{_{—}}ₘᵢₙ and G1_{kullanici}_{_{—}}ₘₐₓ determined by the user.

2. A control method for an audio equipment (1) as in claim 1, characterized by the following steps:
Determination of the minimum audible volume level of the external device (H) by the user and saving of the gain value (G2ₘᵢₙ), corresponding to this level, in the audio equipment (1),
Adjustment of the audio equipment (1) volume to the minimum level desired to be heard by the user in correspondence to the value G2ₘᵢₙ, and saving of the gain value (G1_{kullanici}_{_{—}}ₘᵢₙ), corresponding to this level, in the audio equipment (1),
Determination of the maximum volume level of the external device (H) by the user and saving of the gain value (G2ₘₐₓ), corresponding to this level, in the audio equipment (1),
Adjustment of the audio equipment (1) volume to the maximum level desired to be heard by the user in correspondence to the value G2ₘₐₓ, and saving of equipment (1),
Transmission of the gain value (G2), which corresponds to the new volume level of the external device (H), to the audio equipment (1) as the user changes the volume level of the external device (H),
Calculation of the fraction of the external device (H) new gain value (G2) between the external device (H) gain values G2ₘᵢₙ and G2ₘₐₓ,
Determination of the gain (G1), which will be applied to the audio signal (O2), such that it will correspond to the same fractional value between the gain values G1_{kullanici}_{_{—}}ₘᵢₙ and G1_{kullanici}_{_{—}}ₘₐₓ, which are determined by the user; and
application of the gain (G1) to the audio signal (O2).
